(19) United States
(12) Patent Application Publication
(10) Pub. No.: US 2006/0137994 A1
(43) Pub. Date: Jun. 29, 2006

(54) Method of wafer processing with edge seed layer removal

(76) Inventors: Bulent M. Basol, Manhattan Beach, CA (US); Homayoun Talieh, San Jose, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/782,697

(22) Filed: Feb. 18, 2004

Related U.S. Application Data
(63) Continuation-in-part of application No. 10/032,318, filed on Dec. 21, 2001, now Pat. No. 6,833,063.
(60) Provisional application No. 60/523,064, filed on Nov. 18, 2003.

(51) Int. Cl. C25F 7/00; C01D 3/14; H01L 21/288

(52) U.S. Cl. 205/668; 205/670; 205/771; 205/123

(57) ABSTRACT

A process of forming a conductive layer on a wafer is provided. A front surface and an edge surface of the wafer are coated with a seed layer. Further, the edge surface includes a back edge surface, a bevel surface and a front edge surface. During the process, the seed layer is removed from the back edge surface and the bevel surface using an etching process. Next, the conductive layer is formed by depositing a conductive material onto the remaining seed layer which coats the front edge surface and the front surface of the wafer. A part of the conductive layer which is on the front edge surface is then removed using another etching process.

### RELATED APPLICATIONS

This application claims priority from U.S. Provisional Application Ser. No. 60/523,064 filed Nov. 18, 2003 (NT-315 P), and this application is a continuation in part of U.S. patent application U.S. patent application Ser. No. 10/032,318 filed Dec. 21, 2001 (NT-239), which is incorporated herein by reference.

### FIELD

The present invention generally relates to semiconductor processing technologies and, more particularly, to a system and method that removes a thin conductive layer from the edge region of a workpiece and a process that employs such workpiece to fabricate interconnect structures.

### BACKGROUND

Conventional semiconductor devices generally include a plurality of sequentially formed dielectric interlayers and conductive paths formed on a semiconductor wafer. In an integrated circuit, multiple levels of interconnect networks laterally extend with respect to the wafer surface. Interconnects formed in sequential layers can be electrically connected using vias or contacts. Copper and copper-alloys have recently received considerable attention as interconnect materials because of their superior electro-migration and low resistivity characteristics. Interconnects are usually formed by filling copper in features or cavities etched into the dielectric layers by an electrochemical deposition processes.

In a typical process, first an insulating layer is formed on the wafer surface. Patterning and etching processes are performed to form features or cavities such as trenches and vias in the insulating layer. Then, a barrier/glue layer and then a thin copper seed layer are deposited in the features and the raised portions of the insulating layer. Electroplating current is delivered to the wafer through the seed layer during the following electrochemical deposition step, and the copper layer grows on the seed layer is deposited. The seed layers can be deposited using either physical vapor deposition (PVD) or a chemical vapor deposition (CVD) processes. Either process can deposit a thin copper layer globally onto exposed portions of a wafer. Since the electrical contacts to the seed layer is customarily made along the edge of the wafer, the seed layers are typically extended to and even wrapped around the bevel or edge of the wafers. However, this wrapped around seed layer results in deposition of copper over the edge of the wafer during the electroplating step especially if there is no seal protecting the edge regions from the plating electrolyte.

FIG. 1 illustrates a wafer 10, which is coated with a seed layer 12 and a copper layer 14. Conventionally, a barrier layer is also deposited before the seed layer. However, for clarity, the barrier layer is not included in FIG. 1. The seed layer 12 wraps around the edge 16 or bevel of the wafer and even reaches to a back edge region 19. When electrodeposition is performed on the wafer 10 copper deposits onto the wrapped up edge, if this region is not protected from the plating solution. Edge copper 18, is shown in FIG. 1 and is defined as the deposited material present between the back edge region 19 and the dotted lines 20. The dotted line may correspond to a location that is 0.5-4 mm from the edge of the wafer and typically 1-2 mm from the edge of the wafer. After copper deposition it is customary to anneal the wafers before they are sent to a chemical mechanical polishing (CMP) step or other polishing steps to remove the unwanted overburden copper film left outside of the filled cavities of the wafer surface.

Before annealing the wafer, the edge copper 18 needs to be removed. If it is not removed, the edge copper can easily diffuse during the annealing step into regions of the wafer with active devices because the integrity of the barrier layer at this edge region is not good. Copper diffusion into active areas lowers the device yields and needs to be avoided. The edge copper 18, if not removed, may also cause problems in the wafer processing line by contaminating the wafer transport system through flaking and leaving copper residues on the wafer carriers and other parts of the system. Therefore, it is important to remove the edge copper from the edge of wafers before wafers are moved to the next process step.

This is typically done after the copper electrodeposition process. However, as shown in FIG. 1, in cases where the edge copper 18 is thick, removing the edge copper from the edge region takes a long time. For example, for an edge copper thickness of 2-4 micrometers, depending upon the strength of the etching solution, an etching process of 60-200 seconds may be required. It is especially difficult to remove the copper which is right on the bevel, because etching solutions delivered to the front edge region and the back edge region while the wafer is rotated at high rpm, do not easily wrap around the bevel. During delivery of the etching solution to the edge region for edge copper removal, the wafer is rotated at high rpm (typically 150-550 rpm) to stop the etching solution from migrating to the copper layer 14 on the front surface. Centrifugal forces push the etching solution towards the edge and prevent it to migrate to the inner regions of the front surface. Therefore, higher rpm values are needed to protect the front surface. However, higher rpm values also throw the etching solution off the wafer edge faster and do not allow it to wraparound the bevel effectively. Therefore, copper removal rate from the edge region and especially the bevel is reduced. Long process times to achieve removal of edge copper reduces throughput of the overall process.

To this end, there is a need for removing edge copper in copper plating processes in an efficient and effective manner with high throughput.

### SUMMARY

The present invention provides a method and system for removing a portion of a seed layer from a wafer and depositing a conductive layer on a remaining seed layer. Deposition of the conductive material onto a bevel surface and a back surface edge of a wafer is prevented by removing the seed layer from these locations during an initial etching step prior to the deposition step. The conductive material is formed onto the rest of the seed layer wafer surface and forms a conductive layer. An edge portion of the conductive layer which is on a front edge surface is removed from wafer by another etching step after depositing the layer.

A method of forming a layer of a conductive material on a wafer is provided. A seed layer coats a front surface and an edge surface of the wafer, and the edge surface includes a back edge surface, a bevel surface and a front edge surface. The method includes the steps of removing the seed layer from the back edge surface and the bevel surface, and forming the layer by depositing the conductive material onto the seed layer coating the front edge surface and the front surface of the wafer. At least a part of the layer, which is on the front edge surface, is also removed after the deposition.

In another aspect of the present invention, a method of selectively removing a seed layer from a wafer using a process solution is provided. The seed layer coats a front surface and an edge surface of the wafer, and the edge surface includes a back edge surface, a bevel surface and a front edge surface. The method includes the steps of rotating the wafer, and applying the process solution to the back edge surface so as to remove the seed layer from the back edge surface and the bevel surface by wrapping the process solution around the back edge surface and the bevel surface.

In another aspect of the present invention, a method of forming a layer of a conductive material on a wafer including a front surface, a back surface and an edge surface is provided. The edge surface includes a back edge surface, a bevel surface and a front edge surface. The method includes the steps of depositing a seed layer on the front surface and the edge surface of the wafer, removing the seed layer from the back edge surface and the bevel surface, and forming the layer by depositing the conductive material onto the seed layer coating the front edge surface and the front surface.

In another aspect of the present invention, a method of forming a layer of a conductive material on a wafer using a deposition solution is provided. A seed layer coats a front surface and an edge surface of the wafer, and the edge surface includes a back edge surface, a bevel surface and a front edge surface. The method comprising the steps of removing the seed layer from the back edge surface, the bevel surface and a part of the front edge surface, establishing an electrical contact with a remaining part of the seed layer at the front edge surface, forming the layer by electrodepositing the conductive material onto the seed layer on the remaining part of the front edge surface and the front surface.

These and other features and advantages of the present invention will be described below with reference to the associated drawings.

### BRIEF DESCRIPTION OF THE FIGURES

FIG. 1 is a schematic illustration of an prior art edge copper that has been formed during copper plating of a wafer surface;

FIG. 2A is a schematic illustration of a wafer coated with a seed layer;

FIG. 2B is a detail schematic illustration of an edge region of the wafer shown in FIG. 2A;

FIG. 3 is a schematic illustration of the edge region after the seed layer is removed from a from a back edge and bevel of the edge surface with the process of the present invention;

FIG. 4 is a schematic illustration of a copper layer formed on a remaining seed layer shown in FIG. 3;

FIG. 5 is a schematic illustration of the copper layer shown in FIG. 4, wherein an edge portion of the copper layer has been removed from a front edge of the edge surface;

FIG. 6 is a schematic illustration of an embodiment of a system of the present invention for removing the seed layer from the back edge and the bevel of the edge surface;

FIG. 7 is a schematic illustration of removal of edge copper from the front edge of the edge surface; and

FIG. 8 is a schematic illustration of another embodiment of a system of the present invention for removing the seed layer from the back edge and the bevel of the edge surface.

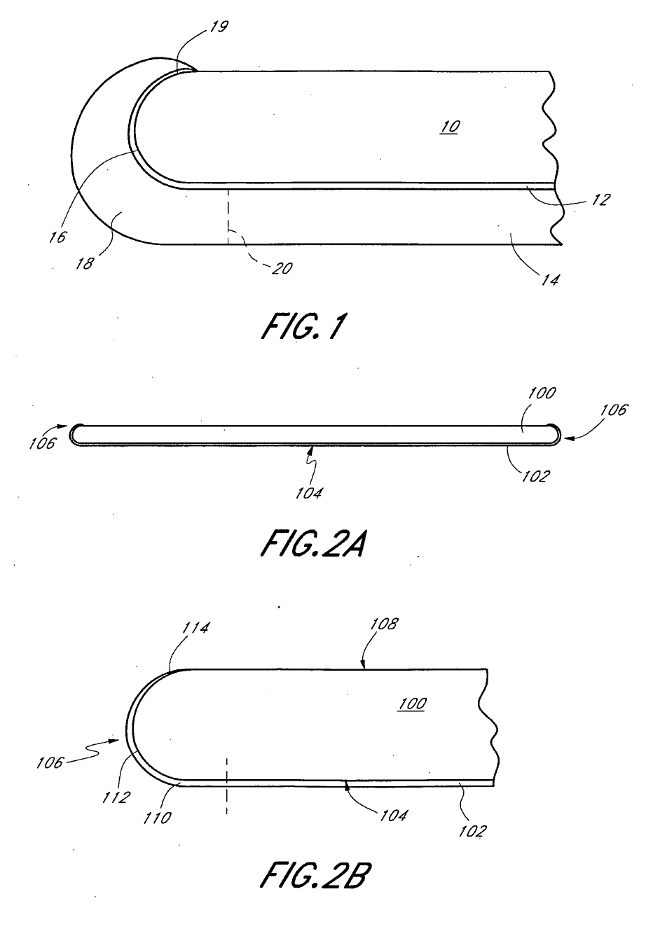

### DESCRIPTION

The present invention provides a method and system for eliminating deposition of a conductive material on an edge region of a wafer having a seed layer on it. As mentioned above, the seed layer coats a front surface of the wafer and then wraps around edge of the wafer. According to principles of the present invention, deposition of the conductive material onto bevel surface and back surface edge of a wafer is prevented by removing the seed layer from these locations during an initial process step. Seed layer removal from the bevel surface and the back surface edge and optionally from a portion of the front surface edge of the wafer, does not allow deposition of conductive material on these locations during the electrochemical deposition process. As a result, the conductive material deposits onto the rest of the wafer surface and forms a conductive layer. In the next process step, the edge portion of the conductive layer is removed from only a front surface edge of the wafer, thereby completing the edge conductor removal process. Removal of the conductive layer from the front surface edge is much easier and has higher throughput compared to prior art removal of the conductive layer from the bevel. In the preferred embodiment, the conductive material is copper and the seed layer is a copper seed layer although invention is applicable to other metallic conductive materials.

During the process, the copper seed layer deposition can be carried out in a PVD or other thin film deposition chamber such as a CVD chamber or atomic layer deposition chamber. After the bevel and back edge copper seed layer removal, wafers are plated using a plating process such as electrochemical deposition (ECD) or electrochemical mechanical deposition (ECMD) process. Although ECD and the ECMD are given as exemplary plating methods, the present invention may be performed using any electrochemical or electroless plating processes. ECMD process produces a planar copper overburden layer on a wafer and descriptions of various ECMD methods and apparatus can be found in the following patents and pending applications, all commonly owned by the assignee of the present invention. U.S. Pat. No. 6,176,992 entitled “Method and Apparatus for Electrochemical Mechanical Deposition,” U.S. Pat. No. 6,354,116 entitled “Plating Method and Apparatus that Creates a Differential Between Additive Disposed on a Top Surface and a Cavity Surface of a Workpiece Using an External Influence,” U.S. Pat. No. 6,471,847 entitled “Method for Forming Electrical Contact with a Semiconductor Substrate” and U.S. Pat. No. 6,610,190 entitled “Method and Apparatus for Electrodeposition of Uniform Film with Minimal Edge Exclusion on Substrate.”

FIG. 2A illustrates a semiconductor wafer 100 having a seed layer 102 deposited on a front surface 104 and an edge region 106 of the wafer 100 using, for example, a PVD process. The front surface 104 of the wafer 100 may be a preprocessed surface having features, and a barrier layer may be deposited on the surface before the seed layer deposition. For clarity, the barrier layer on which the seed layer is deposited is not shown in the drawings. As shown in FIG. 2B, in more detail, the edge region 106 or edge surface is located circumferentially around the wafer between the edge of the front surface 104 and a back surface 108. In FIG. 2B, a portion of the wafer is shown in side view. The dotted line is added to indicate the border that is considered in this example as the border of the edge region on the front surface. In this respect, the edge region 106 is generally comprised of a front edge surface 110 (front edge), bevel surface 112 (bevel) and a back edge surface 114 (back edge). The seed layer 102 coats the front surface 104 and the edge region 106. The front edge 110 and the back edge 114 of the edge region 106 are located adjacent the front surface 104 and the back surface 108 of the wafer respectively. The bevel 112 is the surface between the front edge and the back edge.

As illustrated in FIG. 3, portion of the seed layer 104 covering the bevel 112 and the back edge of the edge region 106 is selectively removed by using a seed layer removal process. The seed layer removal process, which may be a chemical etching, electrochemical etching, polishing, chemical mechanical removal or electrochemical mechanical removal process, may or may not cause a partial removal from the portion of the seed layer that covers the front edge 110 of the edge region 106. In one embodiment, a process solution such as an etching solution having a solution in water of 5-25% sulfuric acid and 5-25% hydrogen peroxide, may be directed towards the back edge of the edge region for a short period of time such as 1-10 seconds to remove the seed layer from the back edge and the bevel since the process solution can wrap around the bevel to a certain extent and since the seed layer thickness is small and removal can be achieved in a short time.

During the delivery of the etching solution to the edge region for seed layer removal, the wafer is rotated at a first predetermined rpm (revolutions per minute) value to stop the etching solution from migrating or flowing to the remaining seed layer on the front edge 110 and the front surface 104. A typical range for the first predetermined rpm value may be between 250 to 550 rpm. As the wafer is rotated, surface tension forces tries to wrap the etching solution around the edge region, and the centrifugal forces oppose such wrap around. When a balance is established between the two forces at a specific rpm, etching solution wraps around the back edge 114 and the bevel surface 112 of the edge region 106 without migrating or flowing to the front edge 110 and the front surface 104. Generally, as rpm value is reduced, extend of wrap-around is increased, i.e., covers larger area along the edge. Therefore, by reducing the rpm value, in addition to the seed layer removal from the back edge and the bevel, it is also possible to remove a part of the seed layer 102 from the front edge 110 in a controlled fashion. In this respect, a second predetermined rpm value may be lower than the first predetermined rpm value, and may be in the range of 150-350.

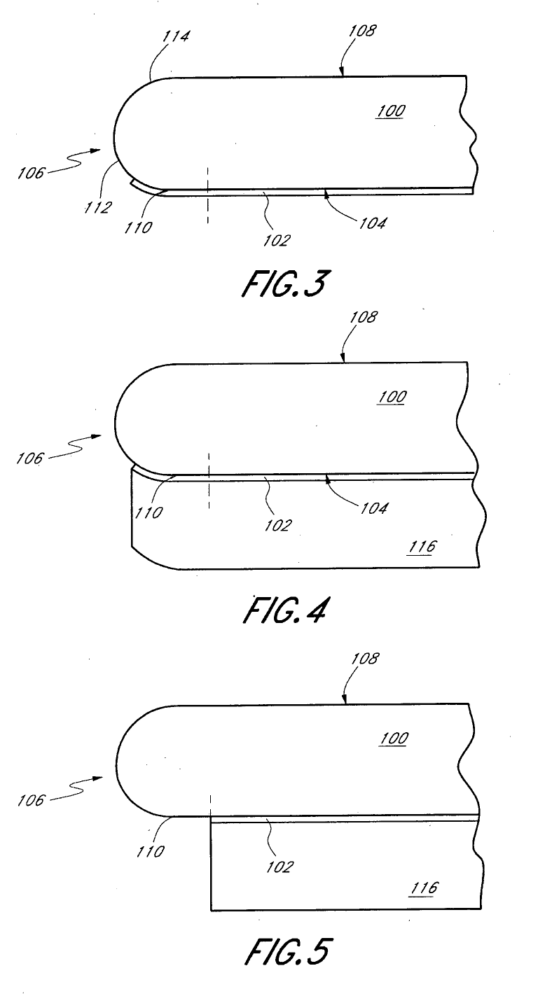

After completing the seed layer removal process from part of the edge region, a copper layer 116 is deposited, as shown in FIG. 4, on the remaining portion of the seed layer 102 using an electrochemical process such as a ECD or ECMD process. During the deposition, electrical contact to the wafer is made through the portion of the seed layer that covers the front edge 110 or elsewhere on the remaining seed layer and the seed layer is wetted by a copper plating solution. The wafer is rotated and may also be laterally moved while the deposition is performed as well described by prior art techniques.

As illustrated in FIG. 5, after the copper deposition step, in a front edge copper removal step, the copper layer 116 that is deposited over the front surface and the front edge, and the underlying seed layer portion, are removed from the front edge region leaving copper only in areas where there are active devices and a good barrier layer. The removal process may be an electrochemical etching or a chemical etching process. In one embodiment, an etching solution may be directed to the front edge of the edge region 106.

FIG. 6 shows a system 200 to conduct the edge seed layer removal process that is described in connection with FIG. 3. In system 200, the wafer 100 is held by a wafer carrier from the back surface 108 of the wafer. A first etching solution flow 204 is directed from a nozzle 206 towards the back edge 114 to remove the seed layer from the back edge 114, bevel 112 and optionally, from a portion of the front edge as the wafer is rotated. As described above, during the process, the wafer can be rotated with a predetermined rpm. However, by varying this rpm value, the extend of seed layer removal from the edge region may be also varied. It should be noted that other means of wafer holding may also be employed during the process. After the seed layer removal, means to rinse the wafer edge and/or dry, for example using a gas stream may be employed. As mentioned above, an important aspect of the process is to hold the wafer without damaging the seed layer and at the same time allowing removal of the seed layer at the edge region by etching.

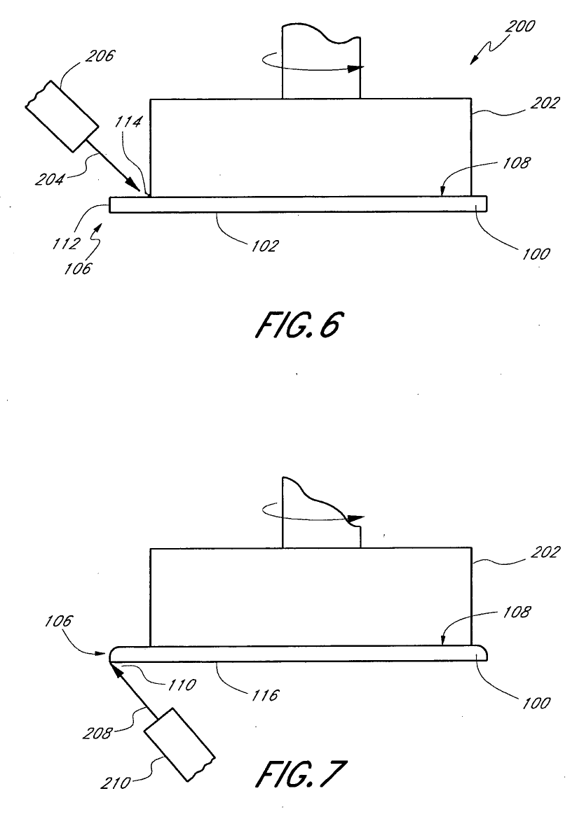

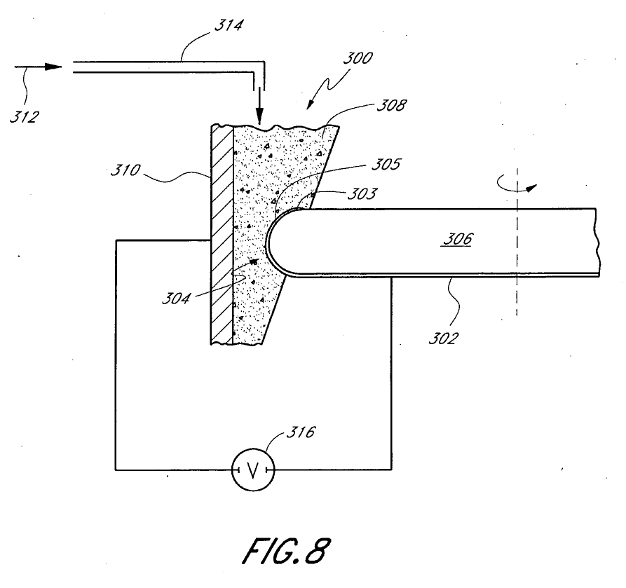

After the edge seed layer removal step, an electrochemical deposition step is carried out, which may be performed while the wafer 100 is still held by the same wafer carrier 202 or a different wafer carrier, copper on the front edge 110 is removed as described in connection with FIG. 7. During the front edge copper removal, an etching solution flow 208 is directed from a second nozzle 210 towards the front edge 110 to remove the copper from front edge as the wafer is rotated.

An alternative edge seed layer removal approach is an electrochemical process. Examples of systems using electrochemical processes to remove edge coppers are described in U.S. application Ser. No. 10/032,318 filed Dec. 21, 2001, owned by the assignee of the present application. FIG. 8 illustrates an electrochemical seed layer removal apparatus 300 to remove the seed layer 302 from a back edge 303 and a bevel 304 of an edge region 305 of a wafer 306 as the wafer is rotated. The apparatus 300 comprises a solution delivery section 308 and an electrode 310. The solution delivery section 308 may be a porous media, for example a spongy material or a brush to apply a process solution 312 to the edge region of the wafer. The delivery section 308 may be made of an insulating or a high resistivity material. Alternatively, the solution delivery section may be a cavity to hold the solution delivery section so that the edge of the wafer is placed into the cavity. The process solution 312, preferably a mild electropolishing or an electroetching solution such as dilute sulfuric acid or salt solution is delivered to the solution delivery section through a solution line 314. The electrode 310 is a conductive material and connected to a terminal of a power source 316, which applies a potential difference between the electrode 310 and the seed layer 302 during the removal process. During the removal process, the edge of the wafer is pressed against the solution delivery section 308 so that the solution delivery section 308 contacts the seed layer 302 covering the back edge 303 and the bevel 305. Alternatively, the solution delivery section 308 may include a cavity to insert the edge of the wafer 306 during the removal process. Once the solution delivery section 308 is saturated with the process solution 312, current is applied through the electrode 310 and the seed layer 302 at the back edge and the bevel is removed while the wafer is rotated by a carrier (not shown). Preferably, a positive voltage is applied to the seed layer with respect to the electrode 310 during this process. After the removal of the seed layer from the back edge and the bevel, the wafer is electroplated as described above. This is then followed by the removal of the edge copper from the front edge of the edge region, as described above.

Although various preferred embodiments have been described in detail above, those skilled in the art will readily appreciate that many modifications of the exemplary embodiment are possible without materially departing from the novel teachings and advantages of this invention.

We claim:

1. A method of forming a layer of a conductive material on a wafer, wherein a seed layer coats a front surface and an edge surface of the wafer, and wherein the edge surface includes a back edge surface, a bevel surface and a front edge surface, the method comprising the steps of:
removing the seed layer from the back edge surface and the bevel surface; and
forming the layer by depositing the conductive material onto the seed layer coating the front edge surface and the front surface of the wafer.

2. The method of claim 1, further comprising the step of removing at least a part of the layer which is on the front edge surface.

3. The method of claim 1, further comprising rotating the wafer during the step of removing the seed layer.

4. The method of claim 3, further comprising the step of applying a process solution onto the back edge surface of the wafer while it is rotated.

5. The method of claim 1, wherein the step of removing comprises chemical etching.

6. The method of claim 1, wherein the step of removing comprises electrochemical etching.

7. The method of claim 2, further comprising rotating the wafer prior to the step of removing the at least a part of the layer.

8. The method of claim 7, further comprising the step of applying a process solution to the at least a part of the layer while the wafer is rotated.

9. The method of claim 8, wherein the step of removing the at least a part of the layer comprises chemical etching.

10. The method of claim 8, wherein the step of removing the at least a part of the layer comprises electrochemical etching.

11. A method of selectively removing a seed layer from a wafer using a process solution, the seed layer coating a front surface and an edge surface of the wafer, wherein the edge surface includes a back edge surface, a bevel surface and a front edge surface, comprising the steps of:
rotating the wafer; and
applying the process solution to the back edge surface so as to remove the seed layer from the back edge surface and the bevel surface by wrapping the process solution around the back edge surface and the bevel surface.

12. The method of claim 11, wherein a potential difference is applied between the seed layer and an electrode contacting the process solution during the step of applying the process solution.

13. The method of claim 11, wherein the step of rotating comprises rotating the wafer at a first predetermined rpm value to prevent the process solution from flowing to the front surface.

14. The method of claim 13, wherein rotating the wafer at the first predetermined rpm value wraps the process solution around the back surface edge and the bevel surface.

15. The method of claim 11, wherein the step of rotating comprises rotating the wafer at a second predetermined rpm value, wherein the second predetermined rpm value wraps the process solution around the back edge surface, the bevel surface and a part of the front edge surface.

16. A method of forming a layer of a conductive material on a wafer comprising a front surface, a back surface and an edge surface, the edge surface including a back edge surface, a bevel surface and a front edge surface, the method comprising the steps of:
depositing a seed layer on the front surface and the edge surface of the wafer;
removing the seed layer from the back edge surface and the bevel surface; and
forming the layer by depositing the conductive material onto the seed layer coating the front edge surface and the front surface.

17. The method of claim 16, further comprising the step of removing a portion of the layer, which is on the front edge surface.

18. The method of claim 16, further comprising rotating the wafer during the step of removing the seed layer.

19. The method of claim 18, further comprising the step of applying a process solution to the back edge surface while the wafer is rotated.

20. The method of claim 16, wherein the step of removing comprises electrochemical removing.

21. The method of claim 16, wherein the step of removing comprises chemical removing.

22. A method of forming a layer of a conductive material on a wafer using a deposition solution, wherein a seed layer coats a front surface and an edge surface of the wafer, and wherein the edge surface includes a back edge surface, a bevel surface and a front edge surface, the method comprising the steps of:
removing the seed layer from the back edge surface, the bevel surface and a part of the front edge surface;
establishing an electrical contact with a remaining part of the seed layer at the front edge surface; and
forming the layer by electrodepositing the conductive material onto the seed layer on the remaining part of the front edge surface and the front surface.

23. The method of claim 22, further comprising the step of applying a potential difference between the seed layer and an electrode contacting the deposition solution subsequent to the step of establishing the electrical contact.

24. The method of claim 23, further comprising the step of removing a portion of the layer, which is on the remaining part of the front edge surface.
